(19) United States
(12) Patent Application Publication
(10) Pub. No.: US 2005/0062052 A1
(43) Pub. Date: Mar. 24, 2005

(54) Panel of organic electroluminescent display

(76) Inventors: Fu-Hsiang Yang, Keelung City (TW); Hsin-Chen Lee, Keelung City (TW); Zhi-Hao Wu, Kaohsiung City (TW); Yih Chang, Jhonghe City (TW)

Correspondence Address: BIRCH STEWART KOLASCH & BIRCH, PO BOX 747, FALLS CHURCH, VA, 22040-0747, US

(21) Appl. No.: 10/944,815

(22) Filed: Sep. 21, 2004

(30) Foreign Application Priority Data
Sep. 23, 2003 (TW) 092126176
Sep. 25, 2003 (TW) 092126504
Oct. 13, 2003 (TW) 092128328

(51) Int. Cl. H01L 29/08; H01L 35/24; H01L 51/00; H01L 27/15; H01L 31/12; H01L 21/76

(52) U.S. Cl. 257/79; 257/40

(57) ABSTRACT

An organic electroluminescent display panel comprises a substrate, at least one organic light-emitting area, at least one protecting layer, at least one isolation layer and at least one protrusion. In this case, the organic light-emitting area comprises a plurality of pixels and is disposed over the substrate. The protecting layer is disposed over the substrate and the organic light-emitting area. The isolation layer is disposed over the protecting layer.

### BACKGROUND OF THE INVENTION

1. Field of Invention

The invention relates to a display panel and, in particular, to an organic electroluminescent display panel.

2. Related Art

The flat-panel displays have been developed with the trend towards high brightness, planar and thinner structures, and power saving. Accordingly, the organic electroluminescent (OEL) display panel is one of the most potential products in optoelectronics industries. The organic electroluminescent display panel uses the self-emitting property of organic functional materials to perform display purposes. The organic electroluminescent display comprises small molecule OLED (SM-OLED) and polymer light-emitting display (PLED) according to the molecular weight of the organic functional materials.

However, the organic electroluminescent component (the organic functional material) is very sensitive to water and oxygen, and may generate dark spots after exposing in atmosphere. Accordingly, in order to maintain the lifetime of the organic electroluminescent component, as shown in FIG. 1, the conventional packaging process utilizes UV-cured resin 31 to seal a cover 32 and a substrate 33 of an organic electroluminescent device 3. In such a case, the organic electroluminescent component 34 is disposed in an airtight space. The conventional organic electroluminescent device 3, however, has a larger dimension, and has an improvement potential to become more lightweight and compact. In addition, water and oxygen can still penetrate through the UV-cured resin 31 and then reach the inside of the organic electroluminescent device 3, which results in a shortened lifetime of the device 3.

In an alternative conventional packaging process, an inorganic film, such as SiₓO_{y}, is directly deposited on the organic electroluminescent component by sputtering, PECVD or electron gun. However, the formed inorganic film is not continuous since the surface of the organic electroluminescent component is not planar. This structure may allow water and oxygen penetrating into the inside of the component through the gaps of the inorganic film. To avoid this problem, as shown in FIG. 2, one solution is to deposit a thicker inorganic film 41 having a thickness of about 0.1 to 10 micrometers for covering the entire organic electroluminescent component 42. The thicker inorganic film 41 may have constricted expansion and contraction behaviors, so that internal stress may occur. In serious situation, the inorganic film 41 may be stripped off. In addition, as shown in FIG. 3, another solution is to evaporate or coat an organic layer 43 as a buffer layer between the inorganic film 41 and the organic electroluminescent component 42. However, since the organic layer 43 has a poor thermal resistance, the high temperature may crack the organic layer 43, which results in the malfunction of this waterproof layer. Moreover, the solvent and water contained in the un-solidified organic layer 43 may erode the organic electroluminescent component 42 if the organic layer 43 is formed by coating. Furthermore, the solidified organic layer 43 may have an outgas issue.

Accompanying the development of portable electronic devices, the conventional glass substrate have failed to satisfy the demands of lightweight and compact due to the disadvantages such as that it is thicker (about 0.4 mm), heavier, easily cracked, larger dimension, and hard to be manufactured. Therefore, utilizing lightweight, impact durable, and flexible plastic substrate to substitute the glass substrate has become the main trend of this art.

However, the permeability of water to the typical plastic substrate (about 10⁻¹-10g/m²/day, room temperature) is quite larger than that to the glass substrate (about 10⁻⁵g/m²/day, room temperature). The isolation ability of plastic substrate to water and oxygen may be insufficient compared with the glass substrate. Thus, it is an important subjective of the invention to enhance the isolation ability of plastic substrates to water and oxygen.

### SUMMARY OF THE INVENTION

In view of the foregoing, the invention is to provide an organic electroluminescent display panel, which can prevent the invasion of water and oxygen.

To achieve the above, an organic electroluminescent display panel of the invention comprises a substrate, at least one organic light-emitting area, at least one protecting layer, at least one isolation layer and at least one protrusion. In the invention, the organic light-emitting area is disposed over the substrate and comprises a plurality of pixels. The protecting layer is disposed over the substrate and the organic light-emitting area, and the isolation layer is disposed over the protecting layer.

To achieve the above, an organic electroluminescent display panel of the invention comprises a substrate, at least one isolation layer, at least one organic light-emitting area and at least one protrusion. In this case, the isolation layer is disposed over the substrate and comprises an inorganic material. The organic light-emitting area is disposed over the isolation layer and comprises at least one pixel.

As mentioned above, the organic electroluminescent display panel of the invention has an isolation layer or encapsulating layer, which is at least one layer structure, disposed on the protecting layer and/or the substrate. Comparing with the prior art, the invention can misalign the pin-hole defects of the multiple isolation layers, so as to compensate the defects of the layers. In addition, at least one layer structure can extend the penetration path of water and oxygen, which can prevent the invasion of water and oxygen into inside of the component. Furthermore, the isolation layer of the invention can comprise several layers with different young's modulus. The layer with a lower young's modulus is sandwiched between the layers with higher young's modulus for providing a buffer effect. Accordingly, the stress between the isolation layers can be decreased. Moreover, a plurality of protrusions can make the isolation layer with a wave-like shape. This structure of the isolation layer can have more contact area and stronger adhesive force with other portions such as the protecting layer and the protrusions. Also, this structure of the isolation layer can decrease the stress caused by thermal expansion.

In addition, the external water and oxygen can be prevented from penetrating into the component through the edge of the protecting layer since the isolation layer or encapsulating layer of the invention is disposed over the protecting layer and the substrate. The protecting layer of the invention can also solve the problem of that the subsequent isolation layer or encapsulating layer is not continuous. As a result, water and oxygen can be prevented from penetrating into the component through the gaps. Moreover, the protrusions of the invention can make the encapsulating layer with a wave-like shape. This structure of the encapsulating layer can have more contact area and stronger adhesive force with other portions such as the protrusions and the substrate. Also, this structure of the encapsulating layer can decrease the stress caused by thermal expansion and contraction. Furthermore, the penetrating path of water and oxygen can be extended, which can decrease the invasion rate of water and oxygen.

### BRIEF DESCRIPTION OF THE DRAWINGS

The invention will become more fully understood from the detailed description given hereinbelow illustration only, and thus is not limitative of the present invention, and wherein:

FIG. 1 is a schematic view showing the packaging method of the conventional organic electroluminescent display panel;

FIG. 2 is a schematic view showing another packaging method of the conventional organic electroluminescent display panel;

FIG. 3 is a schematic view showing an additional packaging method of the conventional organic electroluminescent display panel;

FIGS. 4 to 11 are schematic views showing an organic electroluminescent display panel according to a first embodiment of the invention; and

FIGS. 12 to 13 are schematic views showing an organic electroluminescent display panel according to a second embodiment of the invention.

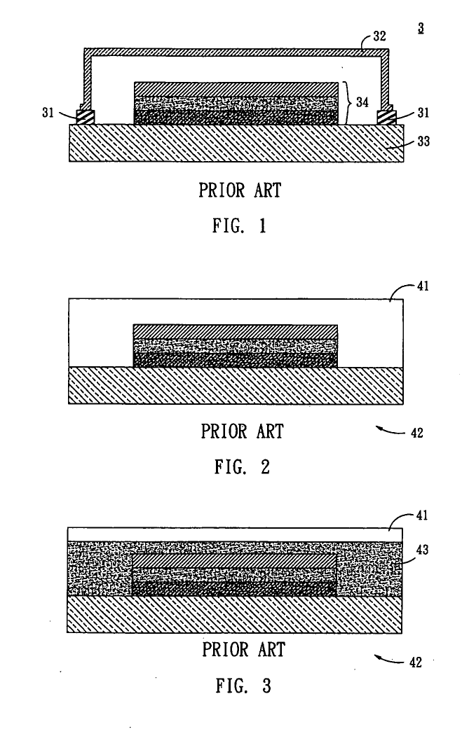

### DETAILED DESCRIPTION OF THE INVENTION

The present invention will be apparent from the following detailed description, which proceeds with reference to the accompanying drawings, wherein the same references relate to the same elements. Hereinafter, the drawings only show a single pixel for concise purpose.

First Embodiment

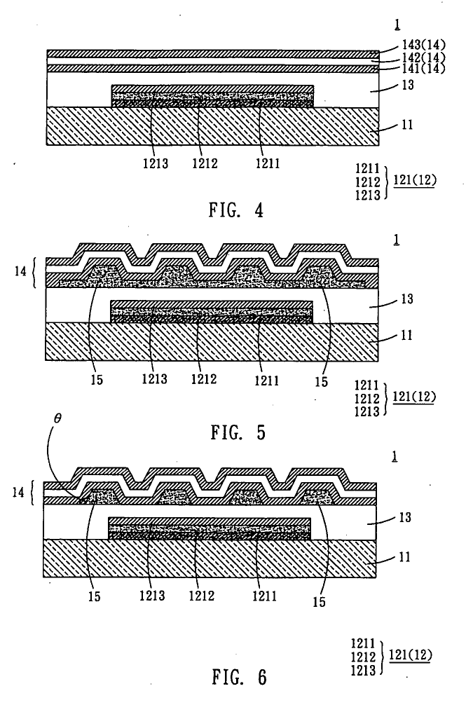

With reference to FIG. 4, an organic electroluminescent display panel 1 according to the first embodiment of the invention comprises a substrate 11, at least one organic light-emitting area 12, at least one protecting layer 13 and at least one isolation layer 14. In the embodiment, the organic light-emitting area 12 is disposed over the substrate 11 and comprises a plurality of pixels 121. The protecting layer 13 is disposed over the substrate 11 and the organic light-emitting area 12. The isolation layer 14 is disposed over the protecting layer 13.

In the present embodiment, the substrate 11 can be a flexible or a rigid substrate. The substrate 11 can also be a plastic or glass substrate. In particular, the flexible substrate or plastic substrate can be made of polycarbonate (PC), polyester (PET), cyclic olefin copolymer (COC), or metallocene-based cyclic olefin copolymer (mCOC). Of course, the substrate 11 can also be a silicon substrate.

Referring to FIG. 4 again, the organic light-emitting area 12 comprises a plurality of pixels 121. Herein, The pixel 121 sequentially comprises a first electrode 1211, at least one organic functional layer 1212 and a second electrode 1213. The first electrode 1211 is disposed on the substrate 11.

In the present embodiment, the first electrode 1211 is formed on the substrate 11 by a sputtering method or an ion plating method. The first electrode 1211 is usually used as an anode and made of a transparent conductive metal oxide, such as indium-tin oxide (ITO), aluminum-zinc oxide (AZO), or indium-zinc oxide (IZO).

The organic functional layer 1212 usually comprises a hole-injecting layer, a hole-transporting layer, a light-emitting layer, an electron-transporting layer and an electron-injecting layer (not shown). The organic functional layer 1212 may be formed upon the first electrode 1211 by utilizing evaporation, spin coating, ink jet printing, or printing. Herein, the light emitted from the organic functional layer 1212 is blue, green, red, white, other monochromic lights, or colorful light.

With reference to FIG. 4, the second electrode 1213 is disposed on the organic functional layer 1212. Herein, the second electrode 1213 can be formed on the organic functional layer 1212 by way of evaporation or sputtering. The material of the second electrode 1213 can be but not limited to aluminum, calcium, magnesium, indium, zinc, manganese, silver, gold, and magnesium alloy. The magnesium alloy can be, for example but not limited to, Mg:Ag alloy, Mg:In alloy, Mg:Sn alloy, Mg:Sb alloy and Mg:Te alloy.

The protecting layer 13, as shown in FIG. 4, is disposed over the substrate 11 and the organic light-emitting area 12. In this case, the protecting layer 13 is formed on the substrate 11 and the organic light-emitting area 12 by photochemical vapor deposition (photo-CVD) such as vacuum ultra-violet chemical vapor deposition (VUV-CVD).

Since the photochemical vapor deposition utilizes photon to excite the reaction gases, the reaction can be performed at lower temperature (approximately lower than 300° C.). In addition, since the protecting layer 13 formed by photochemical vapor deposition has looser structure, the stress inside the layers can be decreased. As a result, the protecting layer 13 can be prevented from being stripped off.

With reference to FIG. 4, the protecting layer 13 of the embodiment has the functions of waterproof and oxygen-proof so as to protect the organic light-emitting area 12 from water and oxygen. In addition, the protecting layer 13 can cover the non-planar organic light-emitting area 12 for planarization. Thus, the later formed layers, such as the isolation layer 14 shown in FIG. 4, can have better uniformity, and the non-continuous layers will not occur. Also, the protecting layer 13 may cover micro particles existing in the manufacturing processes.

In the embodiment, the protecting layer 13 comprises an inorganic material, and, in particular, comprises at least one material selected from the group consisting of silicon oxide (SiO₂), diamond like carbon (DLC), silicon nitride (SiNₓ), silicon oxynitride (SiOₓN_{y}), aluminum oxide (Al₂O₃), and metal (including but not limited to aluminum, copper, gold and silver).

As shown in FIG. 4, a plurality of isolation layers 14 are disposed over the protecting layer 13, wherein at least one of the isolation layers 14 is formed by photochemical vapor deposition. Certainly, at least one of the isolation layers 14 can be formed by sputtering.

As mentioned above, since the isolation layer(s) 14 formed by photochemical vapor deposition has looser structure, the stress inside the layers can be decreased. As a result, the isolation layer(s) 14 can be prevented from being stripped off.

In the current embodiment, the isolation layers 14 comprise an inorganic material, such as at least one material selected from the group consisting of silicon oxide (SiO₂), diamond like carbon (DLC), silicon nitride (SiNₓ), silicon oxynitride (SiOₓN_{y}), aluminum oxide (Al₂O₃), and metal (including but not limited to aluminum, copper, gold and silver). Herein, the isolation layers 14 are waterproof so as to enhance the reliability of the organic electroluminescent display panel 1.

Furthermore, the isolation layers 14 of the embodiment may have the functions of waterproof and buffer. For example, the isolation layers 141 and 143, which are made of silicon nitride (SiNₓ), silicon oxynitride (SiOₓN_{y}), diamond like carbon (DLC), aluminum oxide (Al₂O₃), and metal (including but not limited to aluminum, copper, gold and silver), have excellent waterproof ability so as to prevent the invasion of water and oxygen efficiently. The isolation layer 142 sandwiched between the isolation layers 141 and 143 can be made of silicon oxide (SiO₂) and has inferior mechanical strength. Thus, the isolation layer 142 has a buffer function, so as to decrease the internal stress of the isolation layers 14. This multiple layer structure can misalign the pin-hole defects of the isolation layers 14, so as to compensate the defects of the isolation layers 14. In addition, the multiple layer structure can extend the penetrating path of water, which can enhance the waterproof effect.

With reference to FIG. 5 and FIG. 6, the organic electroluminescent display panel 1 further comprises a plurality of protrusions 15, and the isolation layer(s) 14 is disposed over the protrusions 15 and/or protecting layer 13. In the present embodiment, the protrusions 15 are connected to one another (as shown in FIG. 5); otherwise, the protrusions 15 are separated from one another (as shown in FIG. 6).

In this embodiment, the protrusions 15 comprise a waterproof material, such as but not limited to photo sensitive materials (such as photoresist) or silicon oxide (SiO₂).

Moreover, the shape of the protrusion 15 can be a spot bump or a stripe bump, and the likes. In addition, as shown in FIG. 6, the included angle θ between the side of the protrusion 15 and the protecting layer 13 is greater than or equal to 90°. This structure is for avoiding the later formed non-continuous isolation layer(s) 14, which allows water and oxygen penetrating through the gaps thereof.

As shown in FIG. 5 and FIG. 6, since the isolation layer(s) 14 is disposed over the protrusions 15 and/or the protecting layer 13, the isolation layer(s) 14 presents a wave-like shape. This structure of the isolation layer(s) 14 can not only increase the contact area and provide stronger adhesive force with other portions such as the protecting layer 13 and the protrusions 15, but also decrease the stress caused by thermal expansion.

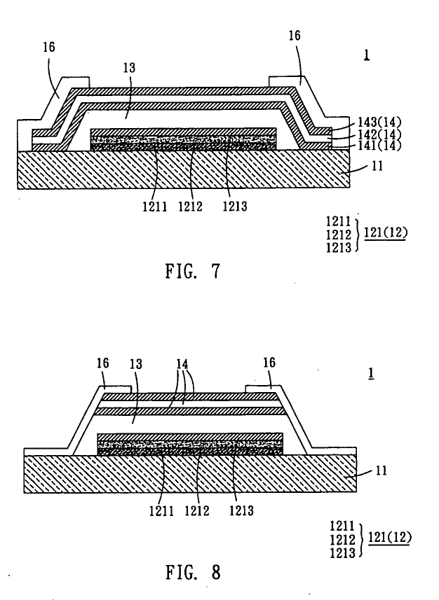

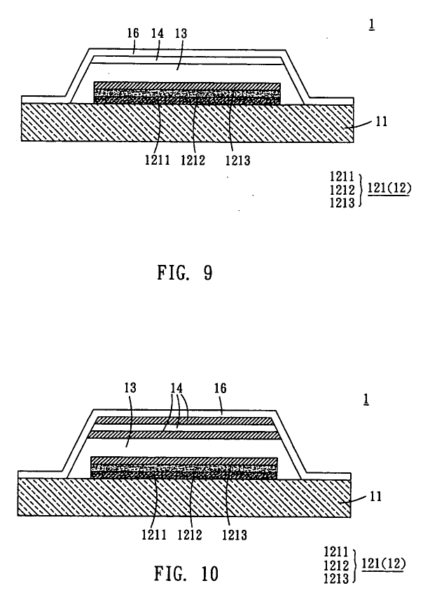

With reference to FIGS. 7 to 10, the organic electroluminescent display panel 1 further comprises an encapsulating layer 16, which is disposed over the substrate 11 and at least covers the edges of the isolation layer(s) 14 and/or the protecting layer 13.

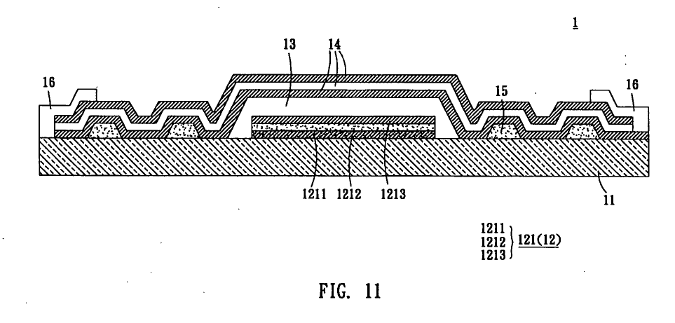

As shown in FIGS. 11 to 14, the protrusions 15 can be disposed over the substrate 11, and the isolation layer(s) 14 can be disposed over the protecting layer 13 and/or the protrusions 15.

In the current embodiment, the encapsulating layer 16 can be formed by photochemical vapor deposition. Certainly, the encapsulating layer 16 can also be formed by sputtering.

The encapsulating layer 16 of the embodiment comprises an inorganic material, which is at least one material selected from the group consisting of silicon oxide (SiO₂), diamond like carbon (DLC), silicon nitride (SiNₓ), silicon oxynitride (SiOₓN_{y}), aluminum oxide (Al₂O₃), and metal (including but not limited to aluminum, copper, gold and silver). Herein, the encapsulating layer 16 is waterproof so as to enhance the reliability of the organic electroluminescent display panel 1.

With reference to FIG. 11, the encapsulating layer 16 may cover the edges of the isolation layer(s) 14. In addition, the encapsulating layer 16 may further cover the edges of the protecting layer (not shown). Of course, the encapsulating layer may completely cover the isolation layer(s), the protecting layer, the protrusions and the substrate (not shown). Since part of the encapsulating layer is disposed over the protrusions, the encapsulating layer may present a wave-like shape (not shown). This structure of the encapsulating layer can not only increase the contact area and provide stronger adhesive force with other portions such as the protrusions and the substrate, but also decrease the stress caused by thermal expansion. Furthermore, the wave-like structure can extend the penetrating path of water and oxygen, which can slow down the invasion speed of water and oxygen.

Second Embodiment

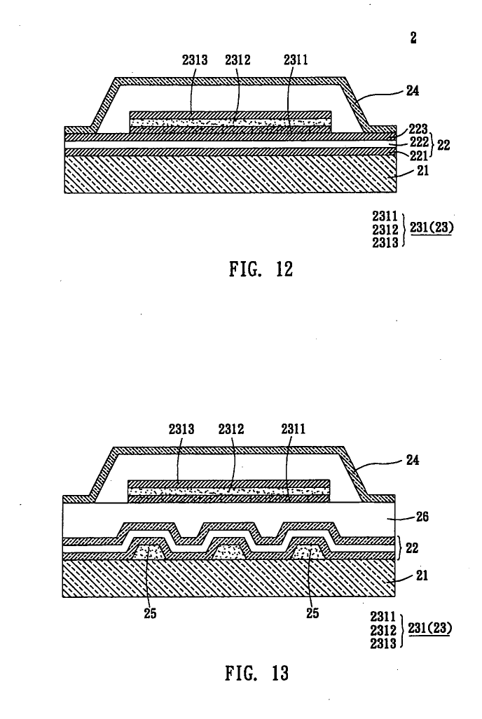

With reference to FIG. 12, an organic electroluminescent display panel 2 according to the second embodiment of the invention comprises a substrate 21, a plurality of isolation layers 22 and at least one organic light-emitting area 23. In the embodiment, the isolation layers 22 are disposed over the substrate 21 and comprise an inorganic material. The organic light-emitting area 23 is disposed over the isolation layers 22 and comprises at least one pixel 231.

The features and functions of the substrate 21, isolation layers 22, organic light-emitting area 23, pixels 231, first electrode 2311, organic functional layer 2312 and second electrode 2313 are the same to those described in the first embodiment, so the detailed descriptions are omitted here for concise purpose.

With reference to FIG. 12 again, the organic electroluminescent display panel 2 further comprises an encapsulating layer 24, which is disposed over the isolation layers 22. Herein, the encapsulating layer 24 can be a cover plate, which is attached to the planar layer 26 with an adhesive. Since the organic light-emitting area 23 (the organic electroluminescent component) is very sensitive to moisture and oxygen, dark spots may be formed when it contacts with air. Therefore, the encapsulating layer 24 is provided to prevent the organic light-emitting area 23 from water and oxygen.

In addition, the organic electroluminescent display panel 2 further comprises a protecting layer (not shown), which covers over the organic light-emitting area 22 and the isolation layers 22. Herein, the protecting layer can also be provided to prevent the organic light-emitting area 23 from water and oxygen.

Referring to FIG. 13, the organic electroluminescent display panel 2 further comprises a plurality of protrusions 25, which disposed over the substrate 21. Herein, the features and functions of the protrusions 25 are the same to the substrate 15 described in the first embodiment, so the detailed descriptions are omitted here for concise purpose.

In addition, with reference to FIG. 11, the organic electroluminescent display panel 2 further comprises a planar layer 26, which disposed between the organic light-emitting layer 23 and the isolation layers 22 and/or the substrate 21. In this embodiment, the planar layer 26 is used to cover the non-planar isolation layers 22 for planarization. Also, the planar layer 26 may further cover the micro particles existing during the manufacturing processes. Moreover, the planar layer 26 also has the functions of waterproof and oxygen-proof, so as to protect the later formed organic light-emitting area 23 from water and oxygen. In the present embodiment, the planar layer 26 comprises an inorganic material, which is at least one material selected from the group consisting of silicon oxide (SiO₂), diamond like carbon (DLC), silicon nitride (SiNₓ), silicon oxynitride (SiOₓN_{y}), and aluminum oxide (Al₂O₃).

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

1. An organic electroluminescent display panel, comprising:
a substrate;
at least one organic light-emitting area, which is disposed over the substrate and comprises a plurality of pixels;
at least one protecting layer, which is disposed over the substrate and the organic light-emitting area;
at least one protrusion; and
at least one isolation layer, which is disposed over the protrusion and/or the protecting layer.

2. The display panel of claim 1, wherein the pixel sequentially comprises a first electrode, at least one organic functional layer and a second electrode.

3. The display panel of claim 2, wherein the first electrode comprises conductive metal oxide.

4. The display panel of claim 2 wherein the second electrode is made of at least one material selected from the group consisting of aluminum, calcium, magnesium, indium, zinc, manganese, silver, gold and magnesium alloy.

5. The display panel of claim 1, wherein the protecting layer and/or the isolation layer comprise an inorganic material.

6. The display panel of claim 5, wherein the inorganic material is at least one selected from the group consisting of silicon oxide, diamond like carbon, silicon nitride, silicon oxynitride, aluminum oxide and metal.

7. The display panel of claim 1, wherein the protrusion is disposed on the protecting layer.

8. The display panel of claim 1, wherein the protrusions are connected to one another or separated from one another.

9. The display panel of claim 1, wherein the protrusions comprise a waterproof material.

10. The display panel of claim 1, wherein the isolation layer is capable of waterproof.

11. The display panel of claim 1, wherein the isolation layer is capable of buffer.

12. The display panel of claim 1, further comprising:
an encapsulating layer, which is disposed over the substrate and at least covers the edges of the isolation layer and/or the protecting layer.

13. The display panel of claim 12, wherein the protrusion is disposed over the substrate, and the encapsulating layer is disposed over the substrate and/or the protrusion.

14. An organic electroluminescent display panel, comprising:
a substrate;
at least one isolation layer, which is disposed over the substrate and comprises an inorganic material;
at least one organic light-emitting area, which is disposed over the isolation layer and comprises at least one pixel; and
at least one protrusion, which is disposed between the substrate and the isolation layer.

15. The display panel of claim 14, wherein the isolation layer comprises at least one material selected from the group consisting of silicon oxide, diamond like carbon, silicon nitride, silicon oxynitride, aluminum oxide and metal.

16. The display panel of claim 14, wherein the isolation layer is capable of waterproof.

17. The display panel of claim 14, wherein the isolation layer is capable of buffer.

18. The display panel of claim 14, wherein the protrusions are connected to one another or separated from one another.

19. The display panel of claim 14, wherein the protrusion comprises a waterproof material.

20. The display panel of claim 14, further comprising:
at least one planar layer, which is disposed between the organic light-emitting area and the isolation layer and/or the substrate.
